(19) United States
(12) Patent Application Publication
(10) Pub. No.: US 2026/0308765 A1
(43) Pub. Date: Oct. 8, 2026

(54) MODULATED REFLECTION BOTTOM COVER PLATE DESIGN FOR CVD NON-UNIFORMITY IMPROVEMENT

(71) Applicant: Applied Materials, Inc., Santa Clara, CA (US)

(72) Inventors: Yao XU, Santa Clara, CA (US); Cheng CHENG, Santa Clara, CA (US); Xi CEN, San Jose, CA (US); Kai WU, Palo Alto, CA (US)

(21) Appl. No.: 19/629,376

(22) Filed: Mar. 26, 2026

Related U.S. Application Data
(60) Provisional application No. 63/784,553, filed on Apr. 7, 2025.

(51) Int. Cl. C23C 16/46; C23C 16/52

(52) U.S. Cl. CPC C23C 16/46; C23C 16/52

(57) ABSTRACT

A bottom cover plate that enables control of radiative heat transfer associated with a heating element inside a chamber for processing a substrate is provided. The bottom cover plate includes a plate body having a central opening configured to be disposed on a shaft of a pedestal of a substrate processing system. The plate body includes a facing surface configured to face a substrate disposed on a substrate support of the pedestal. The bottom cover plate further includes one or more removable emissivity-modifying modules disposed on the facing surface, wherein the one or more removable emissivity-modifying modules define regions having different emissivity. In some embodiments, the plate body includes a plurality of pinholes configured to receive one or more pins for removably retaining the one or more removable emissivity-modifying modules at selected locations on the facing surface.

### CROSS REFERENCE TO RELATED APPLICATIONS

This application claims the benefit of U.S. Provisional Patent Application Serial No. 63/784,553, filed Apr. 7, 2025, which is incorporated by reference herein in its entirety.

### TECHNICAL FIELD

Embodiments described herein generally relate to semiconductor substrate processing chambers and, more particularly, to bottom cover plates and associated emissivity-modifying modules for controlling radiative heat transfer between a heating element and a substrate to improve temperature and process-result uniformity.

### BACKGROUND

Deposition and dry etch processes are used to form layers on and remove all or a portion of one or more layers from, a substrate. For example, it is known to deposit thin metal and dielectric films on substrates, such as directly on a semiconductor substrate or on film layers already formed thereon, using a sputtering process, also known as physical vapor deposition (PVD). Other methods of forming a thin film on a substrate are chemical vapor deposition (CVD) and plasma enhanced CVD (PECVD). Dry etching is commonly used in semiconductor processing to form features in a substrate, or in one or more thin films on the substrate by a reactive ion etch process.

Many thin film deposition and etch processes used in semiconductor and flat panel display production employ substrate processing chambers that are attached to a mainframe of a cluster tool, referred to as a substrate processing system, wherein one or more substrates are loaded into a dedicated processing chamber (e.g., a vacuum chamber) having dedicated hardware therein to support the substrate during a process performed thereon. Maintaining a uniform process temperature can improve process performance, safety, and component life. During the thin film deposition and etch processes, large amounts of heat are generated. The substrate can be affected by the heat generated during processing, which can result in non-uniform temperature throughout the substrate if not adequately controlled. For example, the left side of the substrate may be hotter than the right side. The center of the substrate may be hotter than the edge of the substrate and vice versa. Non-uniform temperatures can result in a non-uniform planar pattern of the substrate, which may include deformation of the substrate and uneven material deposition. Further, the temperatures of the substrate may differ with each processing chamber of the substrate processing system and may result in different amounts and quality of deposition for each processing chamber.

Non-uniform temperatures of the substrate may be caused by several factors. The geometry of the substrate processing chamber may interfere with heat transmission to the substrate or may result in a heat sink to draw heat away from the substrate. For example, heat from a heating element may be drawn to the parts of the processing chamber and not the substrate, resulting in uneven temperatures of the substrate. Processes performed on the substrate may introduce heat into portions of the substrate but not the whole substrate. Maintaining a uniform temperature of the substrate is challenging because there is limited space available inside the substrate processing chamber to implement corrective measures, particularly in existing processing chambers.

Therefore, there is a need for a system and a method of adjusting a planar non-uniformity pattern of the substrate.

### SUMMARY

Embodiments described herein generally relate to a processing chamber suitable for semiconductor substrate processing. More specifically, embodiments described herein relate to bottom cover plates and associated emissivity-modifying modules that control radiative heat transfer from a heating element toward a substrate to improve temperature and process-result uniformity.

In one aspect, a bottom cover plate for use in a substrate processing system is provided. The bottom cover plate includes a plate body having a central opening configured to be disposed on a shaft of a pedestal of the substrate processing system. The plate body includes a facing surface configured to face a substrate disposed on a substrate support of the pedestal. The bottom cover plate further includes one or more removable emissivity-modifying modules coupled with the facing surface, wherein the one or more removable emissivity-modifying modules define regions having different emissivity.

Implementations may include one or more of the following. The plate body has a plurality of pinholes for coupling the one or more removable emissivity-modifying modules to the facing surface of the plate body. The one or more emissivity-modifying modules comprise at least two emissivity-modifying modules. The at least two emissivity-modifying modules have a different shape. The at least two emissivity-modifying modules have a different size. The at least two emissivity-modifying modules have a different emissivity. The one or more emissivity-modifying modules comprise an anodized surface configured to face a substrate disposed on the substrate support of the pedestal. At least one of the one or more emissivity-modifying modules has an emissivity equal to or greater than 0 but less than 0.24. At least one of the one or more emissivity-modifying modules has an emissivity equal to or greater than 0.24 but less than 0.5. At least one of the one or more emissivity-modifying modules has an emissivity equal to or greater than 0.5 but less than 0.9. At least one of the one or more emissivity-modifying modules has an emissivity equal to or greater than 0.9. The one or more removable emissivity-modifying modules have a ring shape, a quadrilateral shape, or a combination thereof. The quadrilateral shape has at least one curved surface. The quadrilateral shape is a trapezoid having at least one curved surface. The quadrilateral shape has two opposing curved surfaces.

In another aspect, a substrate processing system is provided. The substrate processing system includes a processing chamber for processing a substrate. The processing chamber includes a pedestal. The pedestal includes a heating element configured to heat the substrate and a shaft. The processing chamber further includes a bottom cover plate. The bottom cover plate includes a plate body having a central opening configured to be disposed on a shaft of a pedestal of the substrate processing system. The plate body includes a facing surface configured to face a substrate disposed on the substrate support of the pedestal. The bottom cover plate further includes one or more removable emissivity-modifying modules coupled with the facing surface, wherein the one or more removable emissivity-modifying modules define regions having different emissivity.

Implementations may include one or more of the following. The plate body has a plurality of pinholes for coupling the one or more removable emissivity-modifying modules to the facing surface of the plate body. The one or more emissivity-modifying modules comprise at least two emissivity-modifying modules. The at least two emissivity-modifying modules have a different shape. The at least two emissivity-modifying modules have a different size. The at least two emissivity-modifying modules have a different emissivity. The one or more emissivity-modifying modules comprise an anodized surface configured to face a substrate disposed on the substrate support of the pedestal. At least one of the one or more emissivity-modifying modules has an emissivity equal to or greater than 0 but less than 0.24. At least one of the one or more emissivity-modifying modules has an emissivity equal to or greater than 0.24 but less than 0.5. At least one of the one or more emissivity-modifying modules has an emissivity equal to or greater than 0.5 but less than 0.9. At least one of the one or more emissivity-modifying modules has an emissivity equal to or greater than 0.9. The one or more removable emissivity-modifying modules have a ring shape, a quadrilateral shape, or a combination thereof. The quadrilateral shape has at least one curved surface. The quadrilateral shape is a trapezoid having at least one curved surface. The quadrilateral shape has two opposing curved surfaces.

In another aspect, a non-transitory computer readable medium has stored thereon instructions, which, when executed by a processor, causes the process to perform operations of the above apparatus and/or method.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 illustrates a top plan view of a processing system that includes deposition, etching, baking, and curing chambers, in accordance with one or more embodiments of the present disclosure.

FIG. 2 illustrates a cross-sectional view of a bottom cover plate (BCP) installed in a processing chamber of a processing system, according to one embodiment, in accordance with one or more embodiments of the present disclosure.

FIGS. 3A and 3B depict top view and a bottom view, respectively, of a BCP, in accordance with one or more embodiments of the present disclosure.

FIG. 3C depicts a top view of an adapter for positioning a BCP, in accordance with one or more embodiments of the present disclosure.

FIGS. 4A-4C depict top views of example removable emissivity-modifying modules having different shapes, in accordance with one or more embodiments of the present disclosure.

FIG. 5A depicts a top view of a removable emissivity-modifying module installed on a BCP, in accordance with one or more embodiments of the present disclosure.

FIG. 5B depicts a cross-sectional side view of a removable emissivity-modifying module installed on a BCP as is shown in FIG. 5A, in accordance with one or more embodiments of the present disclosure.

FIG. 6 depicts a flowchart of an example method 600 for configuring a bottom cover plate assembly to improve substrate temperature uniformity and/or process-result uniformity, in accordance with one or more embodiments of the present disclosure.

FIG. 7A depicts a top view of an example arrangement of removable emissivity-modifying modules positioned within a common azimuthal sector of a BCP to provide localized emissivity modification, in accordance with one or more embodiments of the present disclosure.

FIG. 7B depicts a top view of an example arrangement of removable emissivity-modifying modules positioned at different radial locations on a BCP to provide annular emissivity modification, in accordance with one or more embodiments of the present disclosure.

FIG. 7C depicts a top view of an example arrangement of removable emissivity-modifying modules positioned at different radial and azimuthal locations on a BCP to provide mixed emissivity modification, in accordance with one or more embodiments of the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

In the following description, numerous specific details are set forth to provide a more thorough understanding of the present disclosure. However, it will be apparent to one of skill in the art that some embodiments of the present disclosure may be practiced without one or more of these specific details. In other instances, well-known features have not been described in order to avoid obscuring one or more embodiments of the present disclosure.

In view of the above, both a challenge and an opportunity exist to improve temperature and process-result uniformity across a substrate in a substrate processing chamber. Accordingly, embodiments described herein provide a bottom cover plate assembly that can be configured to adjust radiative heat transfer from a heating element toward the substrate to reduce non-uniformities during processing.

Embodiments of the disclosure provided herein generally relate to a bottom cover plate (BCP) assembly that enables control of radiative heat transfer associated with a heating element inside a chamber for processing a substrate. The heating element is used to heat the substrate before or during processing and may heat the substrate non-uniformly due to heat losses within the chamber and/or chamber-to-chamber variation. For example, uneven substrate temperature may result in non-uniform material deposition or other non-uniform process results. The BCP assembly may be used to reduce such non-uniformities.

During processing, a temperature distribution of the substrate may include a pattern or gradient such as a linear or radial pattern and may also include local hot spots and/or cool spots. Heat from the heating element may radiate in a direction away from the substrate. The BCP assemblies discussed herein provide an emissivity boundary configured to control radiative heat transfer from the heating element toward the substrate to adjust the temperature distribution of the substrate and compensate for non-uniform heating. In some embodiments, the BCP includes one or more removable emissivity-modifying modules disposed on a facing surface of the BCP, where the one or more removable emissivity-modifying modules define regions having different emissivity including at least one region corresponding to a module surface and at least one region corresponding to an exposed portion of the facing surface. In some embodiments, the BCP includes a plate body having a central opening configured to be disposed on a shaft of a pedestal of the substrate processing system, and the plate body has a plurality of pinholes for coupling and positioning the one or more removable emissivity-modifying modules at different locations. The configurability of the BCP assembly can enable tuning of non-uniformity for different chambers and/or different heating elements.

### Processing System Configuration Examples

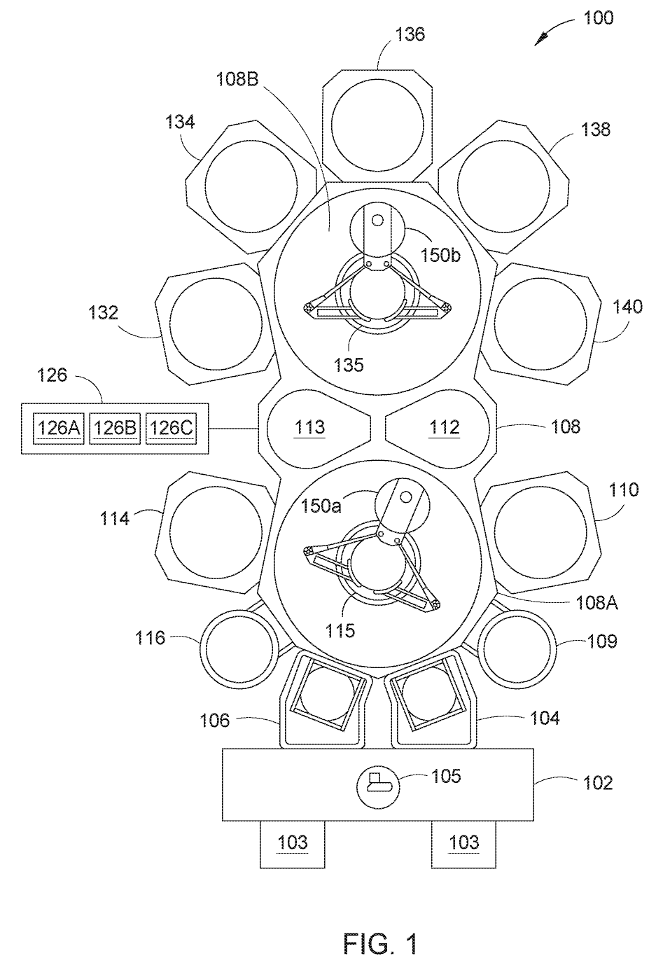

FIG. 1 is a schematic top view of a substrate processing system 100 (also referred to as a “processing platform”), in accordance with one or more embodiments of the present disclosure. The substrate processing system 100 generally includes an equipment front-end module (EFEM) 102 for loading substrates into the substrate processing system 100, a first load lock chamber 104 coupled to the EFEM 102, a transfer chamber 108 coupled to the first load lock chamber 104, and a plurality of other chambers coupled to the transfer chamber 108 as described in detail below. The EFEM 102 generally includes one or more robots 105 that are configured to transfer substrates from the front opening unified pods (FOUPs) 103 to at least one of the first load lock chamber 104 or the second load lock chamber 106. Proceeding counterclockwise around the transfer chamber 108 from the buffer portion 108A of the first load lock chamber 104, the substrate processing system 100 includes a first dedicated degas chamber 109, a first pre-clean chamber 110, a first pass-through chamber 112, a second pass-through chamber 113, a second pre-clean chamber 114, a second degas chamber 116 and the second load lock chamber 106. The buffer portion 108A of the transfer chamber 108 includes a first robot 115 that is configured to transfer substrates 150a to each of the load lock chambers 104, 106, the degas chambers 109, 116, the pre-clean chambers 110, 114 and the pass-through chambers 112, 113.

The back-end portion 108B of the transfer chamber 108 includes a second robot 135 that is configured to transfer substrates 150b to each of the pass-through chambers 112, 113 and the processing chambers coupled to the back-end portion 108B of the substrate processing system 100. The processing chambers can include a first processing chamber 132, a second processing chamber 134, a third processing chamber 136, a fourth processing chamber 138 and a fifth process chamber 140. In general, the processing chambers 132, 134, 136, 138, 140 can include at least one of an atomic layer deposition (ALD) chamber, chemical vapor deposition (CVD) chamber, physical vapor deposition (PVD) chamber, etch chamber, degas chamber, an anneal chamber, and other type of semiconductor substrate processing chamber. In some embodiments, one or more of the processing chambers 132, 134, 136, 138, 140 are a PVD chamber. In some examples, the processing chamber 110 may be capable of performing an etch process, the processing chamber 114 may be capable of performing a cleaning process or an annealing process, and the processing chambers 132, 134, 136, 138, 140 may be capable of performing respective CVD or ALD deposition processes. In one example, the processing chambers 132, 134, 136, 138, or 140 may be a Volta™ CVD/ALD chamber, or Encore™ PVD chambers available from Applied Materials of Santa Clara, Calif.

The buffer portion 108A and back-end portion 108B of the transfer chamber 108 and each chamber coupled to the transfer chamber 108 may be maintained at a vacuum state. As used herein, the term “vacuum” may refer to pressures less than 760 Torr and will typically be maintained at pressures near 10⁻⁵ Torr (that is, ~10⁻³ Pa). However, some high-vacuum systems may operate below near 10⁻⁷ Torr (that is, ~10⁻⁵ Pa). In certain embodiments, the vacuum is created using a rough pump and/or a turbomolecular pump coupled to the transfer chamber 108 and to each of the one or more process chambers (for example, process chambers 109-140). However, other types of vacuum pumps are also contemplated.

A system controller 126 is coupled to the substrate processing system 100 and is configured to control one or more components of the substrate processing system 100, such as one or more of the robots 105, 115, 135 and one or more of the processing chambers 109-140. In operation, the system controller 126 may acquire data from sensors and other components and may provide feedback control signals to coordinate processing operations of the substrate processing system 100.

In some embodiments, the system controller 126 includes one or more processors 126A, memory 126B, and support circuits 126C, and is communicatively coupled to the substrate processing system 100 by one or more wired and/or wireless interfaces to send control signals to and receive status information from, components of the substrate processing system 100. The memory 126B stores instructions that, when executed by the one or more processors 126A, cause the system controller 126 to perform one or more operations described herein, including controlling process conditions in one or more of the processing chambers 109-140. The instructions may be provided as software, firmware, and/or hardware, and may be stored on a non-transitory computer-readable medium associated with the system controller 126.

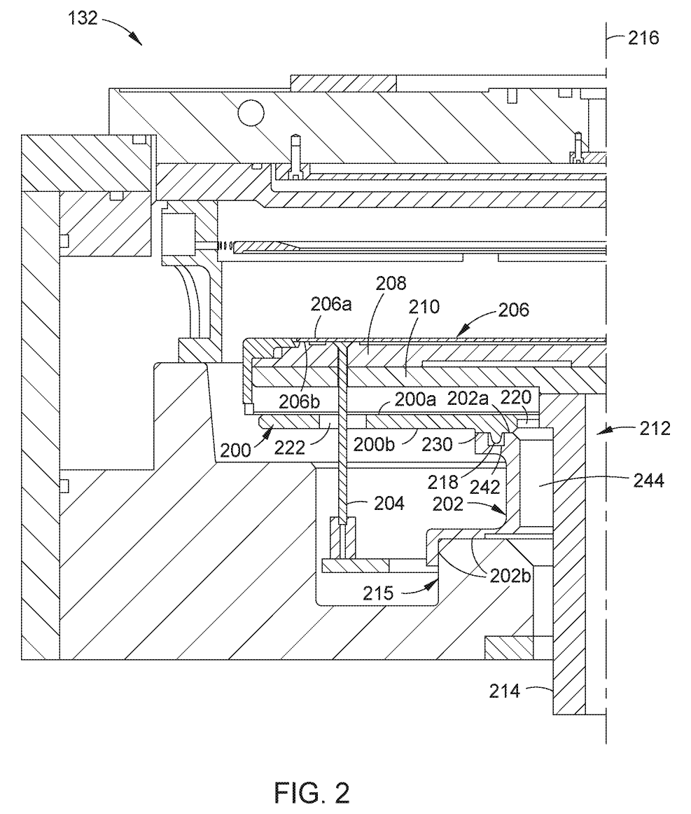

During operation, one or more of the processing chambers 132, 134, 136, 138, or 140 may heat a substrate non-uniformly, for example due to heat losses and/or chamber-to-chamber variation. Such non-uniform heating can contribute to non-uniform deposition or other non-uniform process results. As described in further detail with respect to FIG. 2, at least one processing chamber may include a bottom cover plate assembly configured to control radiative heat transfer to reduce such non-uniformities.

### Bottom Cover Plate Assembly Examples

FIG. 2 depicts a cross-sectional view of a bottom cover plate (BCP) 200 installed in the processing chamber 132 of the substrate processing system 100, in accordance with one or more embodiments of the present disclosure. In particular, FIG. 2 shows an inside of the processing chamber 132, which is used for depositing material on a top surface 206a of a substrate 206. The processing chamber 132 comprises a pedestal 212 having a shaft 214 with a shared central axis 216, a heating element 210, and a substrate support 208. A backside surface 206b of the substrate 206 rests on the substrate support 208. In the depicted embodiment, the pedestal 212 may move vertically to raise and lower the substrate 206 for processing. The pedestal 212 may further comprise the heating element 210 to heat the substrate 206 prior to and/or during processing.

The processing chamber 132 includes the BCP 200. The BCP 200 has a central opening 220, which is disposed on the shaft 214 of the pedestal 212. The heating element 210 is positioned between the BCP 200 and the substrate 206. A facing surface 200a of the BCP 200 faces toward the heating element 210 and a substrate support region that supports the backside surface 206b of the substrate 206. In operation, the BCP 200 may be heated by thermal radiation emitted by the heating element 210 and may control radiative heat transfer toward the substrate 206. In some embodiments, the facing surface 200a is configured to receive one or more removable emissivity-modifying modules attached to the facing surface 200a, where the one or more removable emissivity-modifying modules provide regions having different emissivity to control radiative heat transfer in a selected manner.

The BCP 200 further comprises a mounting surface 200b to orient the BCP 200. In the depicted embodiment, the mounting surface 200b is on an opposite side of the BCP 200 than the facing surface 200a. The mounting surface 200b may interface with an adapter 202, which may be used to position the BCP 200. For example, the mounting surface 200b may engage a top side 202a of the adapter 202. The adapter 202 has a central bore 244, which is disposed on the shaft 214 of the pedestal 212. Thus, the BCP 200 and the adapter 202 may be disposed on the shared central axis 216. A bottom side 202b of the adapter 202 may conform to an existing structure 215 of the processing chamber 132. In some embodiments, the bottom side 202b is removably attached to the existing structure 215. In some embodiments, the bottom side 202b prevents the adapter 202 from rotating.

The BCP 200 comprises an array of keying features 218 (one of which is shown) for fixing the orientation of the BCP 200. The keying features 218 may be disposed on the mounting surface 200b of the BCP 200. In the embodiment shown in FIG. 2, the mounting surface 200b includes a flange 230, which further includes the keying features 218. The top side 202a of the adapter 202 comprises an array of locking features 242 (one of which is shown). The BCP 200 remains stationary when the locking features 242 engage the keying features 218.

The BCP 200 further comprises an array of lift pin through-holes 222 (one of which is shown). In the depicted embodiment, a lift pin 204 travels through the lift pin through-hole 222 in the BCP 200 and other parts of the pedestal 212, such as through the substrate support 208 and the heating element 210. The lift pin through-holes 222 are aligned with the keying features 218 such that the lift pin 204 passes through the lift pin through-hole 222 when the keying features 218 of the BCP 200 engage the locking features 242 of the adapter 202. The lift pin 204 may be one of many lift pins 204 and may lift the substrate 206 off the substrate support 208 when the substrate 206 is transferred to and from the processing chamber 132.

In some embodiments, the BCP 200 includes the adapter 202. For example, the BCP 200 and the adapter 202 may be one piece such that the rotatable portion of the BCP 200 is rotatably attached to the stationary adapter 202. For example, the adapter 202 and the BCP 200 may be separate parts that are affixed together. In another example, the adapter 202 and BCP 200 may be formed into a single part of unitary construction.

In some embodiments, a distance between the BCP 200 and the heating element 210 may be variable. For example, a different adapter 202 may be used to position the BCP 200 closer or further from the heating element 210. In some embodiments, the adapter 202 may comprise an adjustment mechanism to raise or lower the BCP 200 or the adapter 202. For example, the adapter 202 may include adjustable legs to raise and lower the adapter 202 from the processing chamber 132. The adapter 202 may include adjustable columns to raise and lower the BCP 200.

### Bottom Cover Plate Configuration Examples

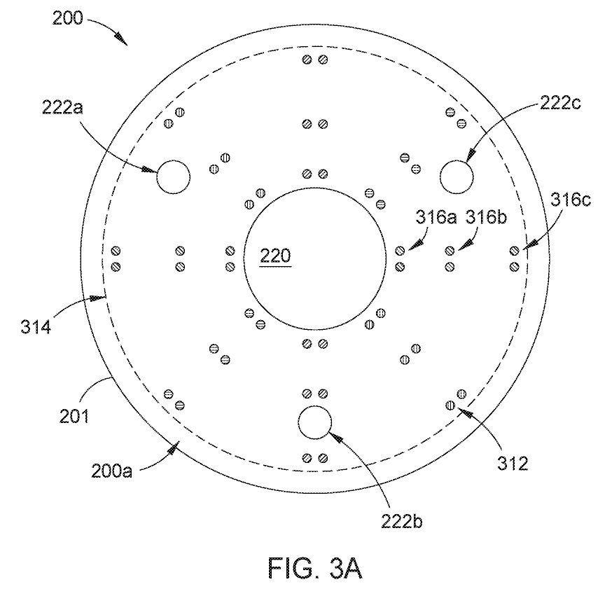

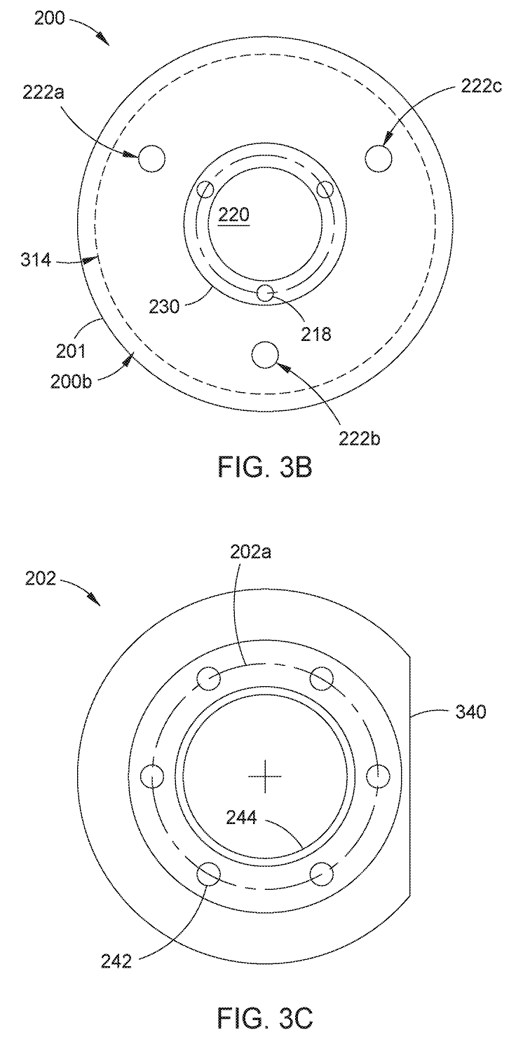

FIG. 3A illustrates a top view of the BCP 200 in accordance with one or more embodiments of the present disclosure. FIG. 3A shows the facing surface 200a of the BCP 200, the central opening 220, and the array of lift pin through-holes 222a-c. In some embodiments, the BCP 200 further includes a plurality of pinholes 312 formed in the plate body 201 and arranged at discrete locations on the facing surface 200a. In some embodiments, the pinholes 312 comprise blind holes that open to the facing surface 200a and do not extend through the plate body 201 to the mounting surface 200b (FIG. 3B). In other embodiments, at least some of the pinholes 312 comprise through-holes that extend through the plate body 201. The plurality of pinholes 312 are configured to receive one or more pins (e.g., pins extending through one or more module through-holes of a removable emissivity-modifying module) to thereby removably couple the removable emissivity-modifying module to the plate body 201. By selecting different ones of the plurality of pinholes 312 for receipt of the one or more pins, the removable emissivity-modifying module is positionable at different locations on the facing surface 200a. In one example, the plurality of pinholes 312 are arranged in the specific pattern shown in FIG. 3A.

In one example embodiment, as shown in FIG. 3A, the module-retention pinholes 312 are arranged in three circumferentially extending rows 316a-316c disposed at three different radial distances from a central axis of the plate body 201, with each row comprising a plurality of pinholes 312 distributed at multiple discrete angular positions about the central axis. A first, inner circumferential row 316a is positioned radially outward of the central opening 220, a second, intermediate circumferential row 316b is positioned radially outward of the inner circumferential row 316a, and a third, outer circumferential row 316c is positioned radially inward of a circular boundary corresponding to the projected substrate edge boundary 314. Within each circumferential row, the pinholes 312 are spaced apart angularly to form partial circumferential patterns extending over multiple angular sectors of the plate body 201, such that the pinholes 312 collectively surround the central axis without forming a single uninterrupted ring. The angular distribution of pinholes 312 in each row is locally interrupted by angular exclusion regions adjacent the lift pin through-holes 222a-222c, with pinholes 312 present on angularly opposite sides of each lift pin through-hole 222a-222c and omitted within clearance regions surrounding those through-holes. As a result, each circumferential row 316a-316c provides a plurality of selectable angular mounting locations at a corresponding radial distance, while maintaining clearance from the central opening 220, the projected substrate edge boundary 314, and the lift pin through-holes 222a-222c. In some embodiments, a diameter of each lift pin through-hole 222a-222c is greater than a diameter of each pinhole 312. In some examples, the lift pin through-holes 222a-222c have a diameter in a range from about 5 mm to about 15 mm (e.g., about 10 mm). In some examples, the pinholes 312 have a diameter in a range from about 0.5 mm to about 2 mm (e.g., about 1 mm). Non-limiting alternatives include other pinhole arrays (e.g., different ring counts, different angular spacings, different sector coverage, and/or different radial placements within the annular region) to provide different placement granularity while still avoiding interference with functional through-holes and wafer-occupied regions. In other embodiments, the plurality of pinholes 312 may be arranged in other patterns and/or at other discrete locations on the plate body 201 to provide different placement granularity for removable emissivity-modifying modules. In some embodiments, the layout of the facing surface 200a is referenced to a projected substrate edge boundary 314 associated with the substrate 206 (FIG. 2) to define regions in which one or more removable emissivity-modifying modules may be positioned.

With reference to FIG. 3A, the BCP 200 includes a plate body 201 having the central opening 220 configured to be disposed on the shaft 214 (FIG. 2). In some embodiments, the plate body 201 comprises a metal material (e.g., aluminum, stainless steel, or a nickel-based alloy) and/or a ceramic material (e.g., aluminum nitride). The plate body 201 includes the facing surface 200a configured to face toward the heating element 210 and the substrate support region. In some embodiments, one or more removable emissivity-modifying modules (e.g., modules described herein) are selectively positionable on the facing surface 200a, such that at least one region corresponding to a module surface and at least one region corresponding to an exposed portion of the facing surface 200a cooperatively provide regions having different emissivity.

In some embodiments, the plate body 201 has a plurality of pinholes 312 for coupling one or more removable emissivity-modifying modules (e.g., modules described herein) to the facing surface 200a of the plate body 201. In some embodiments, each removable emissivity-modifying module includes one or more module through-holes, and one or more pins extend through the one or more module through-holes and are received in corresponding ones of the plurality of pinholes 312 to removably retain the removable emissivity-modifying module on the plate body 201. In embodiments in which the pinholes 312 comprise blind holes, the one or more pins may bottom out in the blind holes. In embodiments in which the pinholes 312 comprise through-holes, the one or more pins may extend through the plate body 201 and may optionally be retained by a clip, fastener, or interference fit on a mounting-surface side of the plate body 201. In some embodiments, the one or more removable emissivity-modifying modules comprise at least two removable emissivity-modifying modules having at least one of different emissivity, different shape, or different size. In some embodiments, at least one removable emissivity-modifying module comprises an anodized surface configured to face the substrate. In some embodiments, at least one removable emissivity-modifying module includes a module surface having an emissivity selected from one of: equal to or greater than 0 but less than 0.24, equal to or greater than 0.24 but less than 0.5, equal to or greater than 0.5 but less than 0.9, or equal to or greater than 0.9, where the emissivity corresponds to a surface finish and/or coating of the module surface. In some embodiments, the one or more removable emissivity-modifying modules include a ring shape, a quadrilateral shape, or a combination thereof, and the quadrilateral shape may include at least one curved edge.

FIG. 3B illustrates a bottom view of the BCP 200. The bottom view shows the mounting surface 200b of the BCP 200, which may interface with the adapter 202 (FIG. 2) to position the BCP 200 within the processing chamber 132. In some embodiments, the mounting surface 200b includes the flange 230, and one or more keying features 218 are disposed on the flange 230 and/or the mounting surface 200b. The one or more keying features 218 are configured to engage corresponding locking features 242 of the adapter 202 to thereby constrain rotation of the BCP 200 relative to the adapter 202 and define one or more discrete rotational orientations of the BCP 200 about the shared central axis 216. In some embodiments, the plurality of pinholes 312 (FIG. 3A) are blind holes opening to the facing surface 200a and therefore are not visible from the mounting surface 200b.

FIG. 3C depicts a top view of the adapter 202 for positioning the BCP 200, in accordance with one or more embodiments. The adapter 202 includes a clocking feature, shown as a straight portion 340, configured to cooperate with a corresponding feature of the existing structure 215 (FIG. 2) to inhibit rotation of the adapter 202 relative to the processing chamber 132. In some embodiments, the adapter 202 includes the plurality of locking features 242 arranged around the central bore 244, and the locking features 242 are configured to receive the keying features 218 of the BCP 200 (FIGS. 2 and 3B) to set the rotational orientation of the BCP 200 relative to the adapter 202.

FIGS. 3A-3C illustrate one example configuration in which the BCP 200 includes three keying features 218 and the adapter 202 includes six locking features 242, although more or fewer features may be used. In some embodiments, the keying features 218 comprise protrusions spaced apart about the central axis 216 at a first angular spacing and positioned at a radius from the central axis 216. In some embodiments, the locking features 242 comprise recesses spaced apart about the central axis 216 at a second angular spacing and positioned at a radius corresponding to the radius of the keying features 218. In the illustrated example, the first angular spacing is about twice the second angular spacing such that engagement of the keying features 218 with different sets of the locking features 242 provides a plurality of discrete rotational orientations of the BCP 200 relative to the adapter 202. Because the adapter 202 is clocked relative to the processing chamber 132 via the clocking feature (e.g., straight portion 340), the discrete rotational orientations of the BCP 200 correspond to discrete angular alignments of features on the facing surface 200a (e.g., the lift pin through-holes 222a–222c and the pinhole array 312 shown in FIG. 3A) relative to the processing chamber 132 and substrate 206 (FIG. 2).

With reference to FIGS. 3A and 3B, the BCP 200 includes the plurality of lift pin through-holes 222a–222c configured to permit corresponding lift pins 204 (FIG. 2) to pass through the BCP 200 at discrete locations. In some embodiments, the lift pin through-holes 222a–222c are positioned at a selected radius and angular spacing about the central axis 216. When the BCP 200 is installed with the keying features 218 engaged with corresponding locking features 242, the lift pin through-holes 222a–222c are aligned with corresponding openings of the heating element 210 and the substrate support 208 to permit travel of the lift pins 204 for substrate transfer. In some embodiments, more or fewer lift pin through-holes 222 may be provided depending on pedestal configuration.

In some embodiments, the number of locking features 242 of the adapter 202 is equal to or greater than the number of keying features 218 of the BCP 200 to provide a plurality of discrete rotational orientations of the BCP 200 relative to the adapter 202. In some embodiments, the BCP 200 includes the locking features 242 and the adapter 202 includes the keying features 218.

Emissivity is a measure of the efficiency with which a surface emits thermal radiation. As discussed with respect to FIG. 2, the heating element 210 is positioned between the substrate 206 and the BCP 200. During operation, thermal radiation emitted by the heating element 210 may be incident on the facing surface 200a of the BCP 200, and thermal radiation emitted by the substrate 206 may be incident on the facing surface 200a of the BCP 200. By providing regions of different emissivity on the facing surface 200a, the BCP 200 can alter radiative heat exchange within the processing chamber 132 to compensate for thermal non-uniformities at the substrate 206 that might otherwise result in non-uniform deposition or other non-uniform process results.

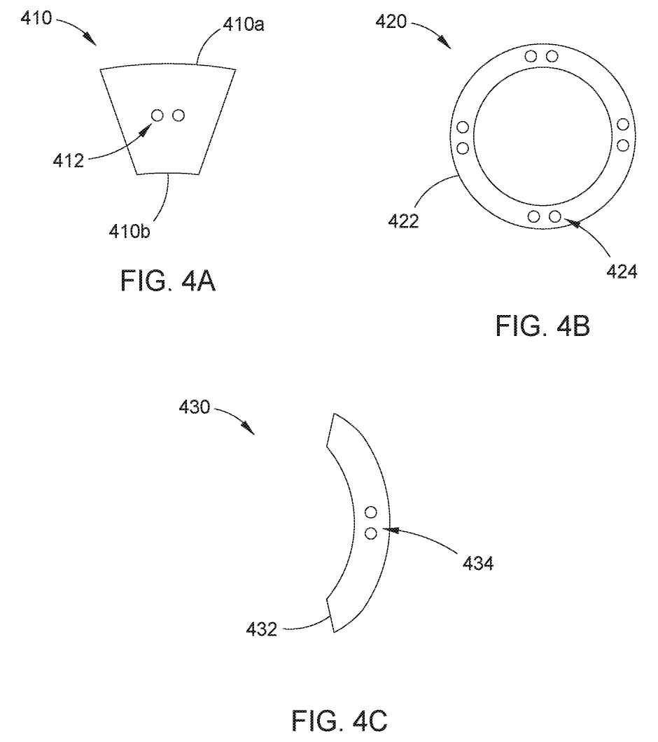

In some embodiments, regions of different emissivity are provided by selectively positioning one or more removable emissivity-modifying modules (e.g., modules 410, 420, 430 (FIGS. 4A-4C)) on the facing surface 200a such that at least one region corresponds to a module surface and at least one region corresponds to an exposed portion of the facing surface 200a. The module surface may be configured (e.g., by material selection, anodizing, coating, and/or surface texturing) to have a higher emissivity than the exposed portion of the facing surface 200a to increase radiative heat transfer toward a corresponding portion of the substrate 206. Additionally or alternatively, the module surface may be configured (e.g., by polishing, reflective coating, and/or reduced surface roughness) to have a lower emissivity than the exposed portion of the facing surface 200a to reduce radiative heat transfer toward a corresponding portion of the substrate 206. In this manner, a selected emissivity distribution on the facing surface 200a can counteract center-high, center-low, edge-high, edge-low, azimuthal, and/or localized non-uniformities, thereby improving temperature and process-result uniformity.

In some embodiments, the emissivity distribution provided by the one or more removable emissivity-modifying modules is selected based on a measured temperature non-uniformity and/or measured process-result non-uniformity. For example, the emissivity distribution may be selected to be an inverse (or partially inverse) profile relative to a measured heat profile of the substrate 206 such that regions associated with lower substrate temperature correspond to higher-emissivity module surfaces and/or regions associated with higher substrate temperature correspond to lower-emissivity module surfaces.

In some embodiments, at least one removable emissivity-modifying module includes a textured surface having a surface roughness different from a surface roughness of the exposed portion of the facing surface 200a. For example, a higher-emissivity module surface may have a greater surface roughness than a lower-emissivity surface, such that selective placement of textured modules on the facing surface 200a provides a selected emissivity distribution for compensating a measured non-uniformity.

In some embodiments, at least one removable emissivity-modifying module includes a module surface having a surface finish configured to provide a selected emissivity. The surface finish may be formed by laser processing, water jetting, bead blasting, and/or chemical texturing. In some embodiments, the surface finish includes a coating. For example, the module surface may include a high-emissivity coating (e.g., a black coating) or a reflective coating, and the coating thickness and/or coverage area may be selected to provide the selected emissivity.

In some embodiments, at least one removable emissivity-modifying module includes a protective coating over an emissivity-providing surface finish and/or coating to reduce damage, contamination, and/or emissivity drift during chamber use.

In some embodiments, a temperature profile and/or process-result profile is measured for a reference substrate processed in the processing chamber 132 (FIG. 2). Based on the measured non-uniformity of the reference substrate, one or more removable emissivity-modifying modules (e.g., modules 410, 420, 430 (FIGS. 4A-4C)) are selected and positioned on the facing surface 200a to provide an emissivity distribution configured to compensate for the measured non-uniformity. The reference substrate may be representative of substrates processed in the processing chamber 132, such that the selected positioning of the one or more removable emissivity-modifying modules may be applied to subsequently processed substrates without measuring a profile for each substrate. In some embodiments, the positioning and/or selection of the one or more removable emissivity-modifying modules is iteratively adjusted based on subsequent measurements.

FIGS. 4A-4C depict example removable emissivity-modifying modules 410, 420, 430 that may be selectively positioned and removably retained on the facing surface 200a of the plate body 201 as described herein.

FIG. 4A depicts a top view of an example removable emissivity-modifying module 410. In some embodiments, the module 410 comprises a generally trapezoidal body having a curved outer edge 410a and a curved inner edge 410b, such that the module 410 is shaped to fit within an annular region of the facing surface 200a (FIG. 3A). In some embodiments, the module 410 includes one or more module through-holes configured to receive one or more pins for removably retaining the module 410 on the plate body 201 as described herein. In some embodiments, the module 410 includes a module surface configured (e.g., by anodizing, coating, and/or surface texturing) to provide a selected emissivity for increasing or decreasing radiative heat transfer in a local region corresponding to the module 410.

In some embodiments, the module 410 comprises a generally planar body having a thickness in a range from about 0.1 mm to about 5 mm (e.g., about 0.5 mm to about 2 mm). In some embodiments, the module 410 comprises a metal material (e.g., aluminum, stainless steel, or a nickel-based alloy), a ceramic material (e.g., aluminum nitride), and/or a polymer material (e.g., a high-temperature polymer), optionally including a surface coating that provides the selected emissivity. In some embodiments, the one or more module through-holes comprise one or more module through-holes 412 configured to receive one or more pins. In some embodiments, the module surface comprises an absorptive finish (e.g., anodized, coated, and/or surface textured) to provide higher emissivity and increase radiative heat transfer in the local region. Additionally or alternatively, the module surface comprises a reflective finish (e.g., polished and/or reflective coated) to provide lower emissivity and reduce radiative heat transfer in the local region.

FIG. 4B depicts a top view of an example removable emissivity-modifying module 420. In some embodiments, the module 420 comprises an annular ring body 422 configured to extend circumferentially about a central axis when installed on the facing surface 200a. In some embodiments, the module 420 includes a plurality of module through-holes 424 distributed circumferentially about the ring body, where the module through-holes 424 are configured to align with corresponding pinholes 312 (FIG. 3A) to receive one or more pins for removably retaining the module 420. In some embodiments, the module 420 provides an azimuthally continuous emissivity modification (e.g., a higher-emissivity ring or a lower-emissivity reflective ring) at a selected radial position relative to the projected substrate edge boundary 314 (FIG. 3A).

In some embodiments, the module 420 comprises a generally planar annular ring body having a thickness in a range from about 0.1 mm to about 5 mm (e.g., about 0.5 mm to about 2 mm). In some embodiments, the module 420 comprises a metal material (e.g., aluminum, stainless steel, or a nickel-based alloy), a ceramic material (e.g., aluminum nitride), and/or a polymer material (e.g., a high-temperature polymer), optionally including a surface coating that provides the selected emissivity. In some embodiments, the plurality of module through-holes comprises a plurality of module through-holes 424 distributed circumferentially about the ring body. In some embodiments, the module 420 comprises an absorptive finish (e.g., anodized, coated, and/or surface textured) to provide higher emissivity, and/or comprises a reflective finish (e.g., polished and/or reflective coated) to provide lower emissivity.

FIG. 4C depicts a top view of an example removable emissivity-modifying module 430. In some embodiments, the module 430 comprises an annular sector (ring-segment) body 432 extending over an angular span less than 360 degrees, such that the module 430 provides localized emissivity modification at a selected azimuthal position on the facing surface 200a. In some embodiments, the module 430 includes one or more module through-holes configured to receive one or more pins for removably retaining the module 430 on the plate body 201. By selecting the azimuthal position of the module 430 (e.g., by selecting different pinholes 312 and/or by selecting a rotational orientation of the BCP 200 as described with respect to FIGS. 3A-3C), the module 430 may be used to compensate for azimuthal and/or localized thermal non-uniformities.

In some embodiments, the module 430 comprises a generally planar annular sector body having a thickness in a range from about 0.1 mm to about 5 mm (e.g., about 0.5 mm to about 2 mm). In some embodiments, the module 430 comprises a metal material (e.g., aluminum, stainless steel, or a nickel-based alloy), a ceramic material (e.g., aluminum nitride), and/or a polymer material (e.g., a high-temperature polymer), optionally including a surface coating that provides the selected emissivity. In some embodiments, the one or more module through-holes comprise one or more module through-holes 434 configured to receive one or more pins. In some embodiments, the module 430 comprises an absorptive finish (e.g., anodized, coated, and/or surface textured) to provide higher emissivity and increase radiative heat transfer in the local region. Additionally or alternatively, the module 430 comprises a reflective finish (e.g., polished and/or reflective coated) to provide lower emissivity and reduce radiative heat transfer in the local region.

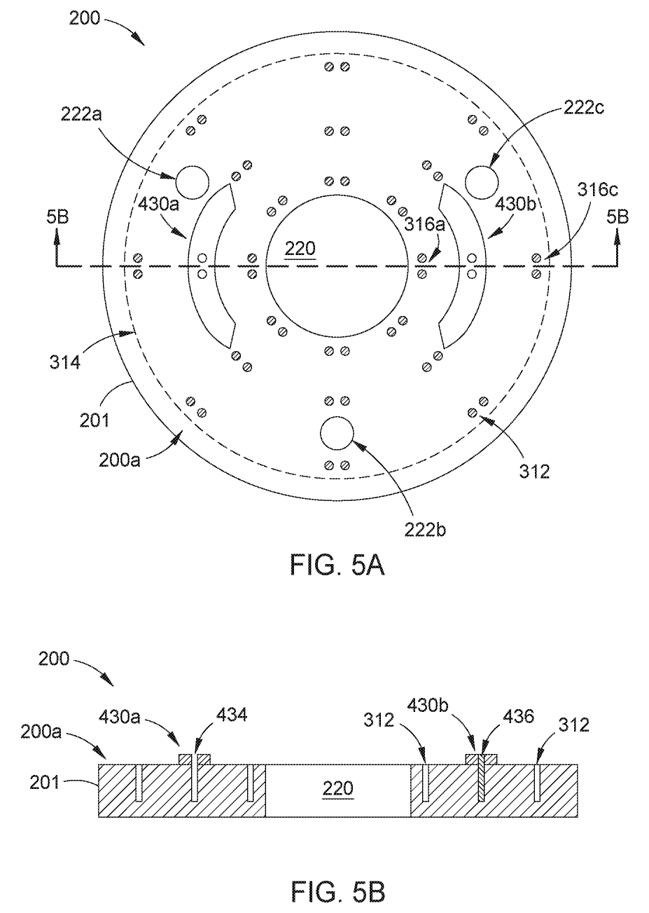

FIG. 5A depicts a top view of removable emissivity-modifying modules 430a, 430b installed on the facing surface 200a of the BCP 200, in accordance with one or more embodiments of the present disclosure. In the illustrated embodiment, the removable emissivity-modifying modules 430a, 430b are positioned in an annular region of the facing surface 200a between the central opening 220 and the projected substrate edge boundary 314. Each removable emissivity-modifying module 430a, 430b extends over an angular span less than 360 degrees to provide a localized emissivity modification at a selected azimuthal position on the facing surface 200a. In the illustrated embodiment, the removable emissivity-modifying modules 430a, 430b are positioned on opposite sides of the central opening 220 such that the removable emissivity-modifying modules 430a, 430b face each other across the central opening 220. In some embodiments, the azimuthal positions of the removable emissivity-modifying modules 430a, 430b are selected to compensate for an azimuthal and/or localized thermal non-uniformity associated with the substrate 206 (FIG. 2). As shown, each removable emissivity-modifying module 430a, 430b includes one or more module through-holes 434 aligned with corresponding selected pinholes 312 of the plate body 201, such that each removable emissivity-modifying module 430a, 430b is removably retained at a selected location on the facing surface 200a.

In some embodiments, the installed removable emissivity-modifying modules 430a, 430b cooperate with exposed portions of the facing surface 200a to define a selected emissivity distribution on the BCP 200. Each removable emissivity-modifying module 430a, 430b may have a module surface configured to provide a higher emissivity than adjacent exposed portions of the facing surface 200a, for example by anodizing, coating, and/or surface texturing, such that the removable emissivity-modifying modules 430a, 430b increase radiative heat transfer in local regions corresponding to the installed positions of the removable emissivity-modifying modules 430a, 430b. Additionally or alternatively, each removable emissivity-modifying module 430a, 430b may have a module surface configured to provide a lower emissivity than adjacent exposed portions of the facing surface 200a, for example by polishing, reflective coating, and/or reduced surface roughness, such that the removable emissivity-modifying modules 430a, 430b reduce radiative heat transfer in the local regions. In some embodiments, the locations of the removable emissivity-modifying modules 430a, 430b on the facing surface 200a are selected by choosing corresponding pinholes 312 in one or more of the circumferential rows 316a-316c shown in FIG. 3A.

FIG. 5B depicts a cross-sectional side view of the removable emissivity-modifying modules 430a, 430b installed on the BCP 200 as shown in FIG. 5A, in accordance with one or more embodiments of the present disclosure. In the illustrated embodiment, the removable emissivity-modifying modules 430a, 430b are disposed on the facing surface 200a of the plate body 201 such that the removable emissivity-modifying modules 430a, 430b overlie selected regions of the plate body 201. A pin 436 extends through the module through-hole 434 of each removable emissivity-modifying module 430a, 430b and into a selected one of the pinholes 312 of the plate body 201. In the example shown, the selected pinhole 312 receiving the pin 436 for each removable emissivity-modifying module 430a, 430b is located in the intermediate circumferential row 316b. The pins 436 removably retain the removable emissivity-modifying modules 430a, 430b on the plate body 201 while permitting removal and replacement of one or both of the removable emissivity-modifying modules 430a, 430b with another module having a different emissivity, shape, and/or size.

In some embodiments, the pinhole 312 receiving the pin 436 for each removable emissivity-modifying module 430a, 430b is a blind hole that opens to the facing surface 200a and terminates within the thickness of the plate body 201. In other embodiments, the pinhole 312 is a through-hole extending through the plate body 201. In embodiments using a through-hole, the pin 436 may extend through the plate body 201 and may optionally be secured by an interference fit, clip, fastener, or other retention structure. In some embodiments, each pin 436 is sized such that the corresponding removable emissivity-modifying module 430a, 430b is removably retained in contact with, or in close proximity to, the facing surface 200a.

In some embodiments, one or both of the removable emissivity-modifying modules 430a, 430b include additional module through-holes 434 configured to receive additional pins 436 for retaining the removable emissivity-modifying modules 430a, 430b in selected angular orientations relative to the plate body 201. By using two or more pins 436 received in corresponding selected pinholes 312 for a given removable emissivity-modifying module 430a, 430b, rotation of that removable emissivity-modifying module 430a, 430b relative to the plate body 201 may be constrained. In some embodiments, one or both of the removable emissivity-modifying modules 430a, 430b are repositionable by removing the one or more pins 436, moving the removable emissivity-modifying module 430a and/or 430b to a different location on the facing surface 200a, and reinserting the one or more pins 436 into different selected pinholes 312. In this manner, the same BCP 200 may be reconfigured to provide different local emissivity distributions for different chambers, different heating elements, and/or different measured non-uniformity patterns.

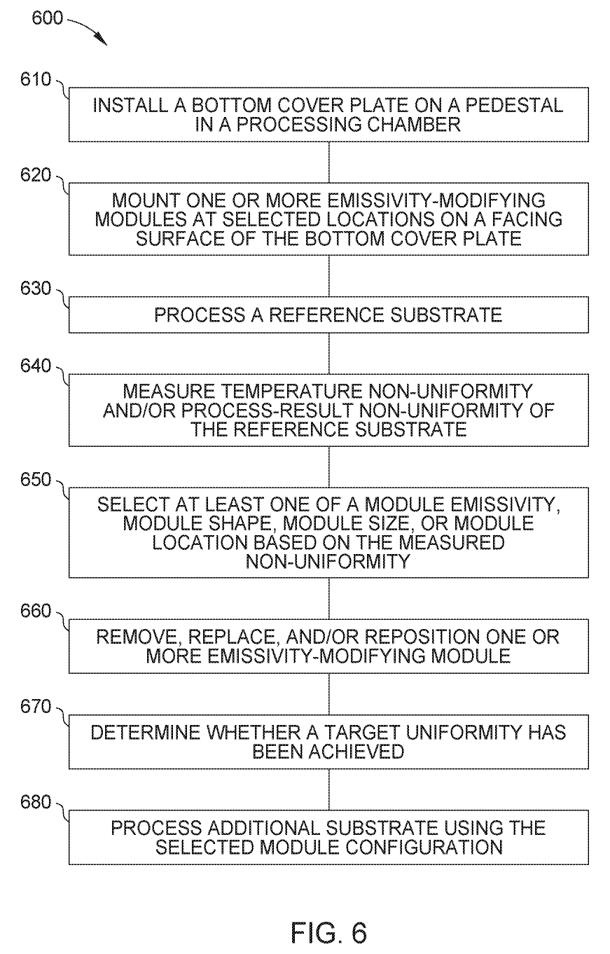

FIG. 6 depicts a flowchart of an example method 600 for configuring the bottom cover plate assembly described with respect to FIGS. 2-5B to improve substrate temperature uniformity and/or process-result uniformity, in accordance with one or more embodiments of the present disclosure.

In some embodiments, the method 600 includes installing the BCP 200 on the pedestal 212 in the processing chamber 132 at operation 610. At operation 620, one or more emissivity-modifying modules, such as modules 410, 420, 430, are mounted at selected locations on the facing surface 200a of the plate body 201. In some embodiments, the one or more emissivity-modifying modules are removably retained on the plate body 201 by one or more pins 436 received in selected pinholes 312 of the plate body 201, as described with respect to FIGS. 3A and 5B.

At operation 630, a reference substrate is processed in the processing chamber 132. In some embodiments, processing the reference substrate comprises performing a deposition process, such as a chemical vapor deposition (CVD) process, an atomic layer deposition (ALD) process, or a physical vapor deposition (PVD) process. In some embodiments, processing the reference substrate comprises performing an etch process and/or a thermal treatment process, such as annealing, degassing, baking, or curing.

At operation 640, a temperature non-uniformity and/or process-result non-uniformity of the reference substrate is measured. In some embodiments, the measured process-result non-uniformity comprises a film-thickness non-uniformity, deposition-rate non-uniformity, sheet-resistance non-uniformity, etch-rate non-uniformity, critical-dimension non-uniformity, or a combination thereof. In some embodiments, the temperature non-uniformity is measured by determining a temperature distribution at a plurality of locations across the reference substrate using thermal imaging, pyrometry, and/or one or more temperature sensors. In some embodiments, the process-result non-uniformity is measured by determining a film-thickness distribution, sheet-resistance distribution, etch-depth distribution, etch-rate distribution, and/or critical-dimension distribution across the reference substrate.

At operation 650, at least one of a module emissivity, module shape, module size, or module location is selected based on the measured non-uniformity. In some embodiments, the selected module configuration provides an emissivity distribution configured to compensate for the measured non-uniformity. For example, the selected module configuration may provide an inverse or partially inverse emissivity profile relative to the measured non-uniformity profile.

At operation 660, one or more emissivity-modifying modules are removed, replaced, and/or repositioned on the facing surface 200a of the BCP 200 according to the selected module configuration. In some embodiments, repositioning includes removing at least one pin 436 from a first selected pinhole 312, moving a corresponding emissivity-modifying module to a different location on the facing surface 200a, and reinserting the at least one pin 436 into a second selected pinhole 312. In some embodiments, replacing includes removing a first emissivity-modifying module having a first emissivity, first shape, and/or first size and installing a second emissivity-modifying module having a second emissivity, second shape, and/or second size different from the first emissivity, first shape, and/or first size.

At operation 670, a determination is made whether a target uniformity has been achieved. If the target uniformity has not been achieved, the method 600 may return to operation 650 and/or operation 660 for further adjustment of the one or more emissivity-modifying modules. If the target uniformity has been achieved, the method 600 may proceed to operation 680, where additional substrates are processed using the selected module configuration.

In some embodiments, the method 600 is performed for a selected processing chamber 132 and/or a selected heating element 210 such that the BCP 200 is customized to compensate for chamber-specific and/or heater-specific non-uniformity. In some embodiments, the selected module configuration determined using the reference substrate is maintained for processing a plurality of production substrates without measuring a non-uniformity profile for each production substrate.

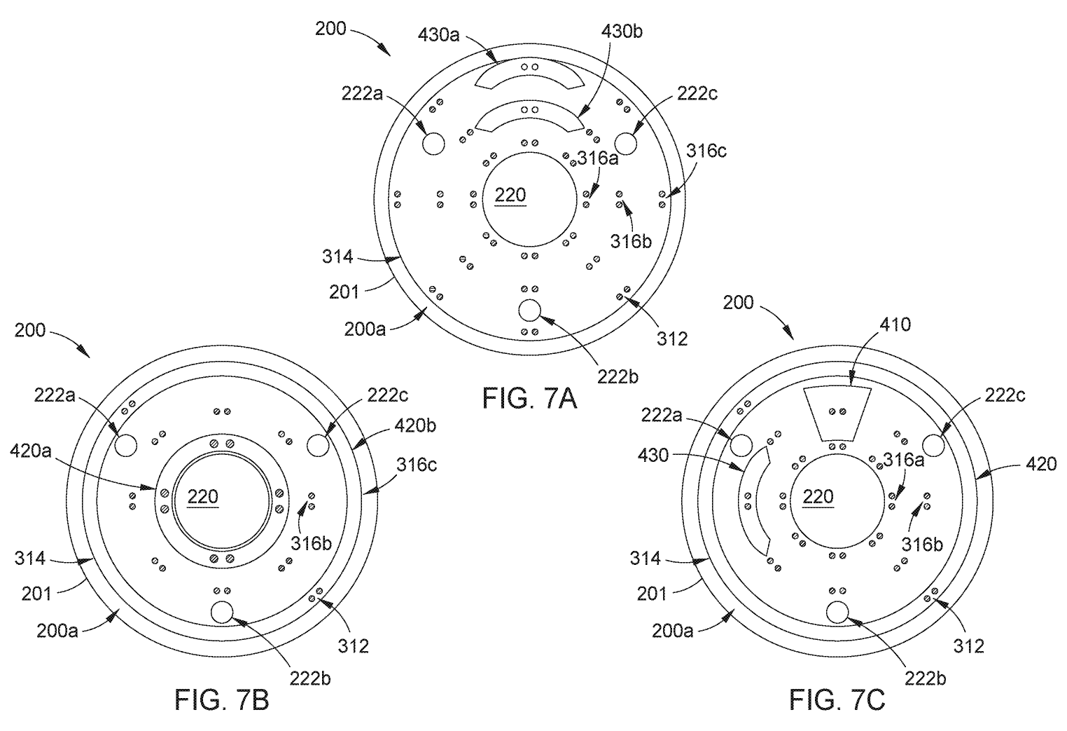

FIGS. 7A-7C depict top views of example selected module configurations of removable emissivity-modifying modules on the facing surface 200a of the BCP 200, in accordance with one or more embodiments of the present disclosure. In some embodiments, the selected module configurations shown in FIGS. 7A-7C provide different emissivity distributions on the facing surface 200a for compensating different temperature non-uniformities and/or process-result non-uniformities. In some embodiments, the removable emissivity-modifying modules are selectively positioned at locations corresponding to selected pinholes 312 in the rows 316a-316c described with respect to FIG. 3A.

In FIG. 7A, a first removable emissivity-modifying module 430a is mounted on the facing surface 200a of the BCP 200 at a location corresponding to the outer circumferential row 316c, and a second removable emissivity-modifying module 430b is mounted adjacent to the first removable emissivity-modifying module 430a at a location corresponding to the intermediate circumferential row 316b. The removable emissivity-modifying modules 430a, 430b are positioned within a common azimuthal sector of the BCP 200 such that the modules 430a, 430b collectively provide a localized emissivity modification extending over a selected angular span and radial extent of the facing surface 200a. In some embodiments, the arrangement shown in FIG. 7A is used to compensate for an azimuthal and/or localized thermal non-uniformity.

In FIG. 7B, a first removable emissivity-modifying module 420a is mounted on the facing surface 200a of the BCP 200 adjacent to the central opening 220 at a location corresponding to the inner circumferential row 316a, and a second removable emissivity-modifying module 420b is mounted on the facing surface 200a adjacent to the projected substrate edge boundary 314 at a location corresponding to the outer circumferential row 316c. In some embodiments, the second removable emissivity-modifying module 420b is positioned radially outward of the first removable emissivity-modifying module 420a. The removable emissivity-modifying modules 420a, 420b collectively provide an annular emissivity-modification pattern at different radial positions on the facing surface 200a. In some embodiments, the arrangement shown in FIG. 7B is used to compensate for a radial thermal non-uniformity, such as a center-high, center-low, edge-high, and/or edge-low non-uniformity.

In FIG. 7C, a removable emissivity-modifying module 420 is mounted on the facing surface 200a of the BCP 200 at a location corresponding to the outer circumferential row 316c, a removable emissivity-modifying module 430 is mounted in a first azimuthal sector corresponding to the intermediate circumferential row 316b, and a removable emissivity-modifying module 410 is mounted in a second azimuthal sector corresponding to the intermediate circumferential row 316b. The removable emissivity-modifying modules 410, 420, 430 collectively provide a mixed emissivity-modification pattern including annular and localized emissivity modification at different positions on the facing surface 200a. In some embodiments, the arrangement shown in FIG. 7C is used to compensate for a combined thermal non-uniformity including both radial and azimuthal components.

Embodiments of the present disclosure provide one or more advantages. By using removable emissivity-modifying modules on the facing surface of the BCP, the BCP may be configured to provide a selected emissivity distribution for compensating temperature non-uniformity and/or process-result non-uniformity associated with a selected processing chamber and/or heating element. Because the removable emissivity-modifying modules are selectively positionable and replaceable, the BCP may be reconfigured without redesigning or replacing the entire pedestal or heating assembly. In some embodiments, the removable emissivity-modifying modules enable chamber-specific and/or heater-specific tuning, reduce chamber-to-chamber variation, improve substrate temperature uniformity, improve deposition and/or etch uniformity, and reduce cost and downtime associated with iterative hardware modification. In some embodiments, the use of different module shapes, sizes, emissivities, and selected locations on the facing surface allows both radial and azimuthal non-uniformities to be addressed using a common BCP platform. However, the present disclosure does not necessitate that all the advantageous features and all the advantages need to be incorporated into every embodiment of the present disclosure.

In the Summary and in the Detailed Description, and the Claims, and in the accompanying drawings, reference is made to particular features (including method operations) of the present disclosure. It is to be understood that the disclosure in this specification includes all possible combinations of such particular features. For example, where a particular feature is disclosed in the context of a particular aspect, implementation, embodiment, or example of the present disclosure, or a particular claim, that feature can also be used, to the extent possible in combination with and/or in the context of other particular aspects and implementations of the present disclosure, and in the present disclosure generally.

The disclosure contemplates that terms such as “couples,” “coupling,” “couple,” and “coupled” may include but are not limited to welding, fusing, melting together, interference fitting, and/or fastening such as by using bolts, threaded connections, pins, and/or screws. The disclosure contemplates that terms such as “couples,” “coupling,” “couple,” and “coupled” may include but are not limited to integrally forming. The disclosure contemplates that terms such as “couples,” “coupling,” “couple,” and “coupled” may include but are not limited to direct coupling and/or indirect coupling, such as indirect coupling through components such as links, blocks, and/or frames.

Embodiments and all of the functional operations described in this specification can be implemented in digital electronic circuitry, or in computer software, firmware, or hardware, including the structural means disclosed in this specification and structural equivalents thereof, or in combinations of them. Embodiments described herein can be implemented as one or more non-transitory computer program products, i.e., one or more computer programs tangibly embodied in a machine-readable storage device, for execution by, or to control the operation of, data processing apparatus, e.g., a programmable processor, a computer, or multiple processors or computers.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

The term “data processing apparatus” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, or a combination of one or more of them.

Computer readable media suitable for storing computer program instructions and data include all forms of nonvolatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

The term “comprises” and grammatical equivalents thereof are used herein to mean that other components, ingredients, operations, etc. are optionally present. For example, an article “comprising” (or “which comprises”) components A, B, and C can consist of (i.e., contain only) components A, B, and C, or can contain not only components A, B, and C but also one or more other components. In addition, whenever a composition, an element or a group of elements is preceded with the transitional phrase “comprising” or grammatical equivalents thereof, it is understood that it is contemplated that the same composition or group of elements may be preceded with transitional phrases “consisting essentially of,” “consisting of,” “selected from the group of consisting of,” or “is” preceding the recitation of the composition, element, or elements and vice versa.

Where reference is made herein to a method comprising two or more defined operations, the defined operations can be carried out in any order or simultaneously (except where the context excludes that possibility), and the method can include one or more other operations which are carried out before any of the defined operations, between two of the defined operations, or after all of the defined operations (except where the context excludes that possibility).

When introducing elements of the present disclosure or exemplary aspects or embodiment(s) thereof, the articles “a,” “an,” “the” and “said” are intended to mean that there are one or more of the elements.

The terms “comprising,” “including” and “having” are intended to be inclusive and mean that there may be additional elements other than the listed elements.

While the foregoing is directed to embodiments of the present disclosure, other and further embodiments of the disclosure may be devised without departing from the basic scope thereof, and the scope thereof is determined by the claims that follow.

What is claimed is:

1. A bottom cover plate for use in a semiconductor substrate processing system, comprising:
a plate body having a central opening configured to be disposed on a shaft of a pedestal of the semiconductor substrate processing system, the plate body comprising:
a facing surface configured to face a substrate disposed on a substrate support of the pedestal;
one or more removable emissivity-modifying modules disposed on the facing surface, the one or more removable emissivity-modifying modules defining regions having different emissivity including at least one region corresponding to a module surface and at least one region corresponding to an exposed portion of the facing surface; and
wherein the plate body has a plurality of pinholes, and wherein each removable emissivity-modifying module is removably retained on the plate body by one or more pins received in corresponding ones of the plurality of pinholes.

2. The bottom cover plate of claim 1, wherein at least one of the one or more removable emissivity-modifying modules comprises a through-hole, and wherein at least one of the one or more pins extends through the through-hole.

3. The bottom cover plate of claim 1, wherein the plurality of pinholes are arranged in an array on the plate body such that the one or more removable emissivity-modifying modules are positionable at different locations on the facing surface by selecting different ones of the pinholes.

4. The bottom cover plate of claim 1, wherein each module is retained by at least two pins received in corresponding pinholes to constrain rotation of the module relative to the plate body.

5. The bottom cover plate of claim 1, wherein at least one of the one or more removable emissivity-modifying modules is replaceable with a different removable emissivity-modifying module to change a local emissivity of the bottom cover plate.

6. The bottom cover plate of claim 1, wherein the one or more removable emissivity-modifying modules comprise at least two removable emissivity-modifying modules.

7. The bottom cover plate of claim 6, wherein the at least two removable emissivity-modifying modules have different shapes.

8. The bottom cover plate of claim 6, wherein the at least two removable emissivity-modifying modules have different sizes.

9. The bottom cover plate of claim 6, wherein the at least two removable emissivity-modifying modules have different emissivities.

10. The bottom cover plate of claim 1, wherein at least one of the one or more removable emissivity-modifying modules comprises an anodized surface configured to face the substrate.

11. The bottom cover plate of claim 1, wherein at least one of the one or more removable emissivity-modifying modules has a ring shape.

12. The bottom cover plate of claim 1, wherein at least one of the one or more removable emissivity-modifying modules has a quadrilateral shape.

13. The bottom cover plate of claim 12, wherein the quadrilateral shape has at least one curved edge.

14. The bottom cover plate of claim 13, wherein the quadrilateral shape is a trapezoid.

15. The bottom cover plate of claim 13, wherein the quadrilateral shape has two opposing curved edges.

16. A substrate processing system, comprising:
a processing chamber for processing a substrate, wherein the processing chamber comprises:
the pedestal, wherein the pedestal comprises:
a substrate support for supporting the substrate
a heating element configured to heat the substrate; and
the shaft; and
the bottom cover plate according to claim 1, wherein the central opening of the plate body is disposed on the shaft.

17. A method of processing a substrate in a substrate processing system, comprising:
disposing a bottom cover plate on a shaft of a pedestal in a processing chamber, the bottom cover plate comprising:
a plate body having a facing surface and a plurality of pinholes;
disposing one or more removable emissivity-modifying modules on the facing surface, the one or more removable emissivity-modifying modules defining regions having different emissivity;
removably retaining each emissivity-modifying module on the plate body by inserting one or more pins into corresponding ones of the plurality of pinholes;
disposing the substrate on a substrate support of the pedestal; and
heating the substrate with a heating element of the pedestal while the bottom cover plate controls radiative heat transfer toward the substrate.

18. The method of claim 17, further comprising removing at least one of the one or more removable emissivity-modifying modules from the facing surface and replacing the removed emissivity-modifying module with a different removable emissivity-modifying module to change a local emissivity of the bottom cover plate.

19. The method of claim 18, wherein the different removable emissivity-modifying module is selected from a plurality of removable emissivity-modifying modules having at least one of different emissivity, different shape, or different size.

20. The method of claim 18, further comprising positioning the different removable emissivity-modifying module on the facing surface based on a measured non-uniformity of at least one of substrate temperature or a process result on a reference substrate processed in the processing chamber.
